(19) United States
(12) Patent Application Publication
(10) Pub. No.: US 2013/0199035 A1
(43) Pub. Date: Aug. 8, 2013

(54) CARRIER FOR MANUFACTURING PRINTED CIRCUIT BOARD AND METHOD FOR MANUFACTURING THE CARRIER

(71) Applicant: SAMSUNG ELECTRO-MECHANICS CO., LTD., Suwon (KR)

(72) Inventors: Kwang Yune Kim, Suwon (KR); Tae Eun Chang, Suwon (KR); Suk Hyeong Cho, Suwon (KR)

(73) Assignee: SAMSUNG ELECTRO-MECHANICS CO., LTD., Suwon (KR)

(21) Appl. No.: 13/753,727

(22) Filed: Jan. 30, 2013

(30) Foreign Application Priority Data
Feb. 2, 2012 (KR) 10-2012-0010915

(51) Int. Cl. H05K 3/42

(52) U.S. Cl. CPC H05K 3/428
USPC 29/852; 29/760

(57) ABSTRACT

Disclosed herein is a carrier for manufacturing a printed circuit board, the carrier including: a core member composed of a base substrate, first metal layers stacked on both surfaces of the base substrate, and second metal layers stacked on the first metal layers; and a protecting unit completely wrapping an outskirt part of the core member, so that physical and chemical stresses can be minimized through a structure where an outskirt part of a carrier is wrapped by a protecting unit, thereby improving the manufacturing yield of the printed circuit board.

### CROSS REFERENCE TO RELATED APPLICATION

This application claims the benefit of Korean Patent Application No. 10-2012-0010915, filed on Feb. 2, 2012, entitled “Carrier for Manufacturing Printed Circuit Board and Method for Manufacturing the Carrier”, which is hereby incorporated by reference in its entirety into this application.

### BACKGROUND OF THE INVENTION

1. Technical Field

The present invention relates to a carrier for manufacturing a printed circuit board and a method for manufacturing the carrier.

2. Description of the Related Art

Generally, a printed circuit board is manufactured by forming wirings of copper foil on one surface of both surfaces of a board made of various thermosetting synthetic resins, to thereby fixedly dispose integrated circuits (ICs) or electronic components on the board, implementing electrical wirings therebetween, and then coating the electrical wirings using an insulator.

Recently, in accordance with the development of electronic industry, the demand for multi-functional and slim and light electronic components has rapidly increased. Therefore, a printed circuit board having the electronic components mounted thereon has also been demanded to have high density wiring and a thin thickness. Particularly, a coreless substrate capable of reducing the entire thickness by removing a core substrate in order to respond to the thin thickness of the printed circuit board and shortening the signal process time has received attention. In addition, since an odd numbered layer-coreless substrate may be designed according to the customers, a carrier member that can conduct a support function in the manufacturing process of the coreless substrate is needed, and thus, the use of the carrier member allows the manufacture of the odd numbered layer-coreless substrate.

That is, a wiring board is manufactured by using a carrier functioning as a support, and then finally, the wiring board is removed from the carrier, thereby realizing one layer of wiring circuit having an insulation distance corresponding to a thickness of a thin film. Here, the carrier needs to have a structure and a design enough to bear physical and chemical stress in a substrate manufacturing process before the wiring board is removed from the carrier. In the prior art, in order to protect the metal layer of the carrier, which is used to implement an odd numbered layer-thin film wiring substrate, from liquid permeation, four surfaces of an outer frame of the substrate may be subjected to hole processing and plating. This method is disclosed in, for example, Korean Patent Laid-Open Publication No. 2011-0060623. However, although it is anticipated that hole processing and plating serve to hold a core member from both sides thereof in order to prevent the separation between metal layers, the distance between holes, the number of holes, and the like cannot be unlimitedly increased, and thus liquid permeation may frequently occur.

### SUMMARY OF THE INVENTION

The present inventors found that, at the time of manufacturing a printed circuit board, physical and chemical stresses can be minimized through a structure where an outskirt part of a carrier is wrapped by a protecting unit, and completed the present invention based thereon.

The present invention has been made in an effort to provide a carrier for manufacturing a printed circuit board capable of preventing external impact and permeation of liquid through a carrier structure where an outskirt part of a core member is completely wrapped by a protecting unit. Also, the present invention has been made in an effort to provide a method for manufacturing a carrier for manufacturing a printed circuit board, capable of forming a predetermined sized buffer zone by applying a hole punching process and an X-ray process at the time of manufacturing the carrier to conduct uniform trimming regardless of elasticity of a product.

According to one preferred embodiment of the present invention, there is provided a carrier for manufacturing a printed circuit board, the carrier including: a core member composed of a base substrate, first metal layers stacked on both surfaces of the base substrate, and second metal layers stacked on the first metal layers; and a protecting unit completely wrapping an outskirt part of the core member.

The first and second metal layers may be formed of copper.

The core member may have a thickness of 0.05˜0.1 mm.

The protecting unit may be a frame formed of a prepreg.

The protecting unit may have a buffer zone with a size of 200˜600 μm.

According to another preferred embodiment of the present invention, there is provided a method for manufacturing a carrier for manufacturing a printed circuit board, the method including: forming a core member by stacking first metal layers on both surfaces of a base substrate and then stacking each of second metal layers on one surface of each of the first metal layers; performing hole punching on the core member such that a distance between holes is 500 mm; forming a protecting unit by stacking a protecting member on the core member and then performing pressing thereon, the protecting unit completely wrapping an outskirt part of the core member; and forming a buffer zone by trimming the protecting unit.

The protecting member may be designed to be larger than the core member by 5 mm or greater.

The first and second metal layers may be formed of copper.

The core member may have a thickness of 0.05˜0.1 mm.

The protecting unit may be a frame formed of a prepreg.

The protecting unit may have a buffer zone with a size of 200˜600 μm.

In the forming of the buffer zone, the trimming may be performed based on the distance between the holes formed in the core member.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross sectional view showing a structure of a carrier according to a preferred embodiment of the present invention;

FIG. 2 is a plane view showing a size and a structure of a buffer zone according to the preferred embodiment of the present invention;

FIG. 3 shows graphs of drop impact test results of the carrier manufactured according to the preferred embodiment of the present invention; and

FIGS. 4A and 4B are microscopic images showing breakage of the buffer zone of the carrier manufactured according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

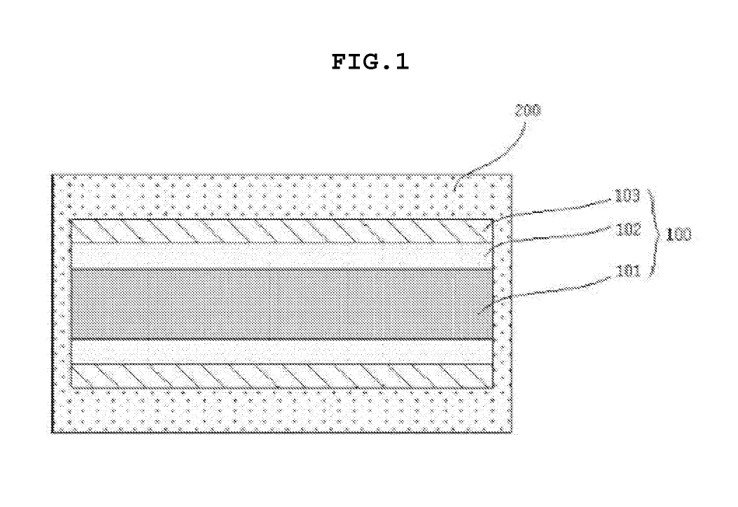

FIG. 1 is a cross sectional view showing a structure of a carrier according to a preferred embodiment of the present invention. As shown in FIG. 1, a carrier for manufacturing a printed circuit board according to a preferred embodiment of the present invention may include: a core member 100 composed of a base substrate 101, first metal layers 102 stacked on both surfaces of the base substrate 101, and second metal layers 103 stacked on the first metal layers 102, respectively; and a protecting unit 200 completely wrapping an outskirt part of the core member 100.

The base substrate 101 is generally composed of an epoxy resin. The first metal layers 102, as two sheets of members, are stacked on both surfaces of the base substrate 101, and later, separated from each other in a manufacturing procedure of the printed circuit board later. The first metal layers 102 are preferably formed of copper.

The second metal layers 103 are formed on the first metal layers 102, and later, constitute the printed circuit board. Here, since the second metal layers 103 may be the outermost circuit layers, they are preferably formed of an electrically conductive metal, such as, gold, silver, copper, nickel, or the like.

The protecting unit 200 wraps an outskirt part of the core member 100 composed of the base substrate 101, the first metal layers 102, and the second metal layers 103, and may be formed of a prepreg having a frame configuration.

When the protecting member is stacked on the core member 100 such that a size thereof is 5 mm or greater, and subjected to a pressing stage, the protecting unit 200 is formed and has a structure where it wraps even both side surfaces of the core member 100. The thus formed protecting unit 200 can protect the core member 100 from permeation of liquid between the first metal layer 102 and the second metal layer 103 and physical impact at the time of manufacturing a printed circuit board.

The core member has a thickness of preferably 0.05˜1 mm, and more preferably 0.05 mm for preventing the printed circuit board from being broken at the time of physical impact.

In addition, the protecting unit is trimmed so that a buffer zone thereof has a size of preferably 200˜600 μm, and more preferably 200 μm for preventing the printed circuit board from being broken at the time of physical impact.

Meanwhile, with respect to a method for manufacturing a carrier for manufacturing a printed circuit board of the present invention, a core member is formed by stacking first layers 102 on both surfaces of a base substrate 101 and then stacking second metal layers 103 each on one surface of each of the first metal layers. Then, hole punching is performed on the thus formed core member such that the distance between holes is 500 nm. Then, a protecting member is stacked on the core member, followed by pressing, to thereby form a protecting unit completely wrapping an outskirt part of the core member. The thus formed protecting unit is trimmed to form a buffer zone.

Here, the protecting member needs to be designed to be larger than the core member by 5 mm or greater so that the protecting unit completely wraps the core member 100. In order to form a buffer zone by processing the thus formed protecting unit, the size of the buffer zone is designed based on the distance between holes formed in the core member by using an X-ray, and then trimming is performed.

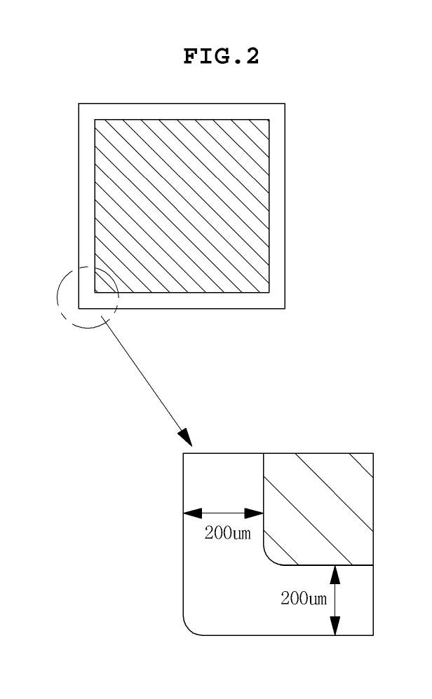

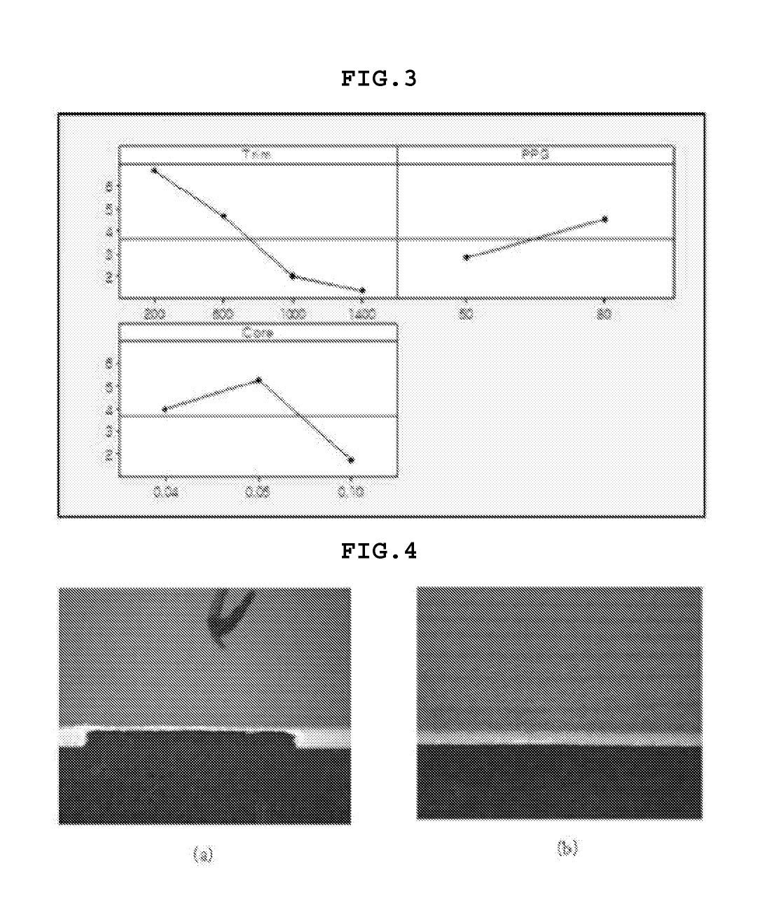

FIG. 2 is a plan view showing size and structure of a buffer zone according to the preferred embodiment of the present invention; and FIG. 3 shows graphs of drop impact test results of the carrier manufactured according to the preferred embodiment of the present invention. Referring to FIGS. 2 and 3, it can be seen that the buffer zone withstood physical impact well when the size thereof was about 200 μm.

FIGS. 4A and 4B are microscopic images showing breakage of the buffer zone of the carrier manufactured according to the preferred embodiment of the present invention. It can be seen that, in the case of FIG. 4A, an impact test result where the buffer zone was processed to have a size 200 μm showed only slight scratch, and in the case of FIG. 4B, an impact test result where the buffer zone was processed to have a size of 200 μm or greater showed remarkable breakage.

As set forth above, according to the present invention, the outskirt part of the carrier is completely wrapped by the protecting unit, to thereby minimize physical and chemical stresses occurring at the time of manufacturing the printed circuit board and thus improve the manufacturing yield of the printed circuit board. Further, when the buffer zone for preventing external impact is formed, the size of the buffer zone can be uniformly formed regardless of elasticity of a product through hole punching and X-ray processing.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A carrier for manufacturing a printed circuit board, the carrier comprising:
a core member composed of a base substrate, first metal layers stacked on both surfaces of the base substrate, and second metal layers stacked on the first metal layers; and
a protecting unit completely wrapping an outskirt part of the core member.

2. The carrier as set forth in claim 1, wherein the first and second metal layers are formed of copper.

3. The carrier as set forth in claim 1, wherein the core member has a thickness of 0.05˜0.1 mm.

4. The carrier as set forth in claim 1, wherein the protecting unit is a frame formed of a prepreg.

5. The carrier as set forth in claim 1, wherein the protecting unit has a buffer zone with a size of 200˜600 μm.

6. A method for manufacturing a carrier for manufacturing a printed circuit board, the method comprising:
forming a core member by stacking first metal layers on both surfaces of a base substrate and then stacking each of second metal layers on one surface of each of the first metal layers;
performing hole punching on the core member such that a distance between holes is 500 mm;
forming a protecting unit by stacking a protecting member on the core member and then performing pressing thereon, the protecting unit completely wrapping an outskirt part of the core member; and
forming a buffer zone by trimming the protecting unit.

7. The method as set forth in claim 6, wherein the protecting member is designed to be larger than the core member by 5 mm or greater.

8. The method as set forth in claim 6, wherein the first and second metal layers are formed of copper.

9. The method as set forth in claim 6, wherein the core member has a thickness of 0.05˜0.1 mm.

10. The method as set forth in claim 6, wherein the protecting unit is a frame formed of a prepreg.

11. The method as set forth in claim 6, wherein the protecting unit has a buffer zone with a size of 200˜600 μm.

12. The method as set forth in claim 6, wherein in the forming of the buffer zone, the trimming is performed based on the distance between the holes formed in the core member.
